(19) United States
(12) Patent Application Publication
(10) Pub. No.: US 2013/0049555 A1
(43) Pub. Date: Feb. 28, 2013

(54) SELECTIVE PLATING OF FRAME LID ASSEMBLY

(71) Applicants: Kothandapani RAMESH, Ang Mo Kio (SG); Thomas deGUEHERY, Buffalo, NY (US); Chee Kong Lee, Singapore (SG)

(72) Inventors: Kothandapani RAMESH, Ang Mo Kio (SG); Thomas deGUEHERY, Buffalo, NY (US); Chee Kong Lee, Singapore (SG)

(21) Appl. No.: 13/588,255

(22) Filed: Aug. 17, 2012

Related U.S. Application Data
(60) Provisional application No. 61/524,526, filed on Aug. 17, 2011.

(51) Int. Cl. C25D 5/02; C25D 17/06; H05K 5/02; C23C 14/34

(52) U.S. Cl. 312/223.1; 205/122; 204/192.1; 204/297.05

(57) ABSTRACT

Disclosed in this specification is selectively plated lead frame assembly and a method for the production thereof. A nickel-plated substrate is selectively masked to protect the bottom surface and a central portion of the top surface of the substrate. Gold is then plated on the unmasked portions. A preformed solder ring is soldered to the exposed gold.

### CROSS-REFERENCE TO RELATED APPLICATIONS

This application claims priority to and the benefit of U.S. provisional patent application Ser. No. 61/524,526, filed Aug. 17, 2011, which application is incorporated herein by reference in its entirety.

### FIELD OF THE INVENTION

This invention relates, in one embodiment, to a method for manufacturing a frame lid assembly that has been selectively plated with gold.

### BACKGROUND

Frame lids are used for hermetically sealing certain electronic components in semiconductor packages. Traditionally, a metal substrate is stamped to provide a surface on the formed lid for soldering the lid to a package base which has been mounted to the electronic components. After stamping, the substrate is nickel plated followed by plating of the entire surface with a thin layer of gold. A solder (e.g. a lead-based alloy) preform whose shape corresponds to the area to be soldered is placed on the gold layer. To hermetically seal the package, the solder is heated to cause it to flow. Unfortunately, the manner in which the solder flows is difficult to control and defects are common. It would therefore be desirable to develop an alternate method for producing frame lid assemblies that minimizes the quantity and/or severity of these defects.

### SUMMARY OF THE INVENTION

The invention comprises, in one form thereof, a method for manufacturing a frame lid assembly for subsequent use in hermetically sealing an electronic component such as a semiconductor chip. To form the lid, a substrate is first plated with nickel. Thereafter a mask is used to selectively protect the bottom surface and a central portion of the top surface of the substrate. Gold is then plated on the unmasked portions. Advantageously, the selective plating controls the solder flow that occurs during subsequent heating steps. Furthermore, the mask also reduces the amount of gold needed to produce the leads and thereby lowers the cost of manufacturing.

### BRIEF DESCRIPTION OF THE DRAWINGS

The present invention is disclosed with reference to the accompanying drawings, wherein:

FIG. 1 is a flow diagram of one process for producing a frame lid assembly;

FIGS. 2A-2I are depictions of various defects in prior art frame lid assemblies;

FIG. 3 is a flow diagram of one process of the invention;

FIGS. 4A-4D provide several views of frame lid assemblies of the invention;

FIG. 5 is a flow diagram of another process of the invention;

FIG. 6 is another flow diagram of another process of the invention;

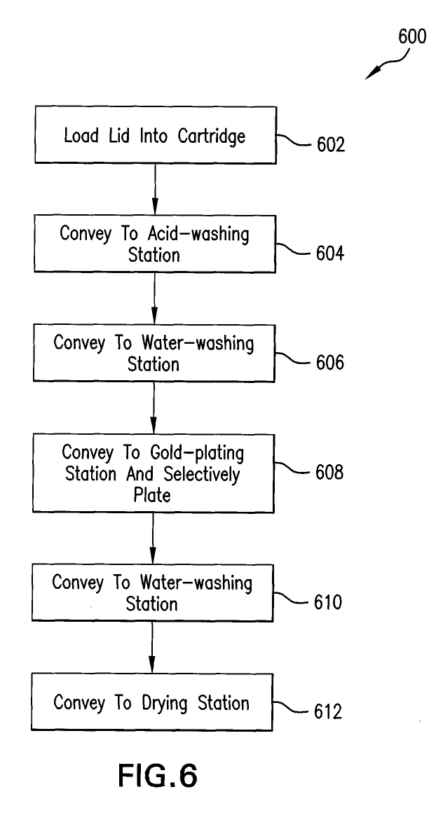

FIG. 7A is a schematic depiction of the various stations of one machine of the invention;

FIG. 7B is a schematic illustration of a cartridge and mask for use with the present invention while FIGS. 7C and 7D are views of the working surfaces of the masks;

FIG. 8 illustrates several pieces for use in the present invention; and

FIGS. 9A and 9B are depictions of a hermetically sealed package.

Corresponding reference characters indicate corresponding parts throughout the several views. The examples set out herein illustrate several embodiments of the invention but should not be construed as limiting the scope of the invention in any manner.

### DETAILED DESCRIPTION

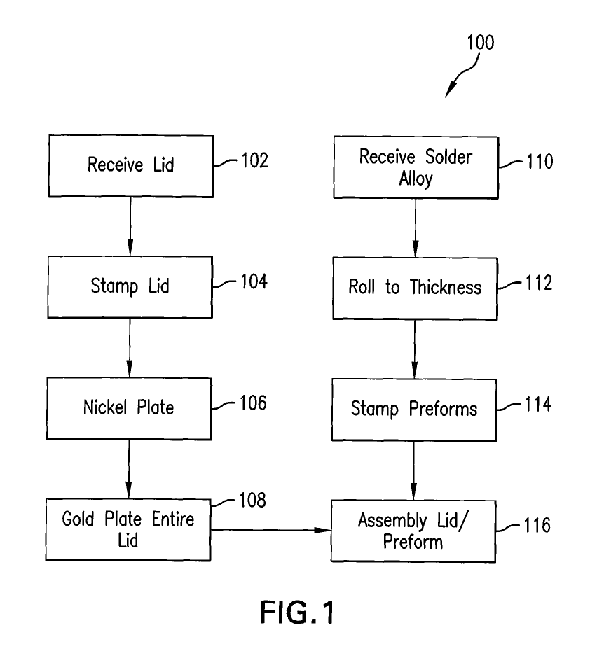

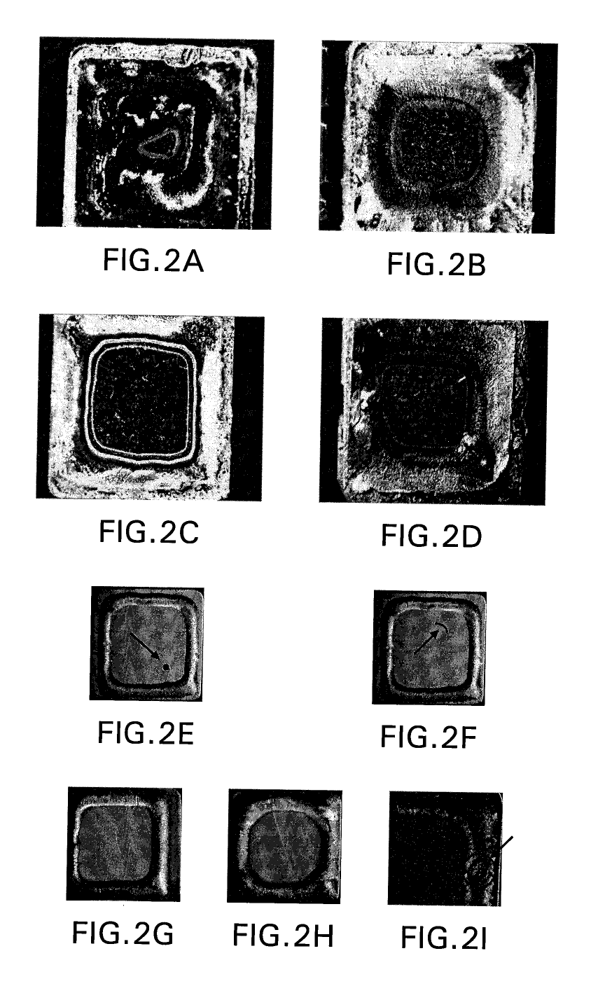

Referring to FIG. 1, a flow diagram of prior art process 100 is depicted. Process 100 begins with step 102 wherein a lid is received and subsequently stamped (step 104) to form a desired shape. In step 106 the lid is plated with nickel followed by plating the entire nickel surface with a thin layer of gold (step 108). In a parallel process, a solder preform is made by first receiving a solder alloy (step 110) and forming it to a desired thickness (step 112). The solder is then stamped (step 114) to form a specific shape. In step 116 the gold-plated lid and solder preform are assembled. Thereafter, these lids are mounted to a surface that supports an electronic component to hermetically seal the component. Such electronic compounds include, but are not limited to, semiconductor chips and the like. Unfortunately defects, some of which are illustrated in FIGS. 2A-2I, are relatively common. FIGS. 2A-2D depict solder flowing over the gold surface to intrude on the central portion that will eventually house the electrical component. Solder grains (FIG. 2E) or strands (FIG. 2F) are also produced in the central portion. FIG. 2G depicts an unacceptable degree of solder “pull back” from the right-hand edge. FIG. 2H shows solder that has lost the square profile of the original solder as the edges became rounded during solder reflow. FIG. 2I illustrates pits/voids in the solder. Each of these defects are considered undesirable.

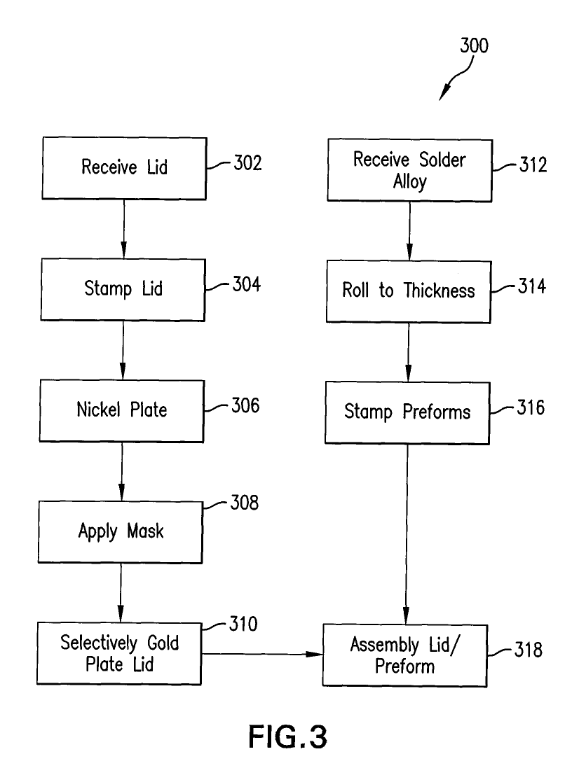

FIG. 3 depicts a process flow diagram of one process of the invention wherein the lids are selectively plated with gold. Advantageously, this selective gold plating helps prevent many of the aforementioned defects. Additionally, due to the reduced consumption of gold, the resulting frame lid assemblies are less expensive relative to their fully plated counterparts.

In step 302, a lid is received. The lids may be formed from any suitable material. In one embodiment, the lid is formed from an iron-alloy. Examples of such iron-alloys include iron-nickel alloys (e.g. 42% Ni:Fe, also known as A42), iron-nickel-cobalt alloys (e.g. 29% Ni; 17% cobalt with the balance being iron, also known as Kovar).

In step 304, the lids are stamped to form a predetermined shape. The desired shape varies depending on the final use of the frame lid assembly. Examples of such shapes include squares and rectangles of various sizes as well as other shapes such as those available from the Materion Corporation.

In step 306 the lid is plated with nickel over its entire surface. In one embodiment, the plating methodology is electroplating. Other suitable methods of plating are also contemplated including sputtering, chemical vapor deposition, and the like. In one embodiment, the nickel layer has a thickness of from about 1 μm to about 6 μm. In another embodiment, the nickel layer has a thickness of from about 3 μm to about 5 μm.

In step 308, a mask is applied to cover certain portions of the nickel-plated lid while leaving certain other portions exposed for subsequent gold-plating. In the embodiment shown, the portions to be gold-plated include the vertical edges of the lid as well as the periphery of the top surface of the lid. The bottom of the lid as well as the center portion of the lid's top surface are protected by the mask and are therefore not plated in gold.

In step 310, the masked substrate is selectively plated with gold. In a parallel process (steps 312, 314, and 315) a solder preform is produced. The preformed solder may be any suitable material (e.g. lead-based or lead free solders including, for example, 80:20 AuSn solder). These steps parallel steps 110, 112 and 114 of process 100. The gold-plating is performed in accordance with standard procedures. For example, Military Specification MIL-G-45204B Type III, Grade A, for 2-5 minutes at a temperature of 60° C. may be used. A variable amount of time can be used to control the thickness of the gold. In one embodiment, the gold layer is from about 0.1 μm to about 0.6 μm. In another embodiment, the gold layer is about 10% the thickness of the nickel layer. In yet another embodiment, the gold layer is about 0.3 μm thick. The solder preform is stamped to have a shape that corresponds to the shape of the gold on the selectively plated lid. For example, if the gold is selectively plated in a square shape, the solder preform is likewise a square of corresponding size. In certain embodiments, it is desirable to design the solder preform such that it is slightly smaller than the gold to which it will eventually attach—thereby permitting the edge of the gold to be visible where the gold contacts the exposed nickel surface.

In step 318, the solder preform is attached to the lid. The solder preform is disposed on the gold surface such that the solder and gold are in contact. The preform is attached onto the lid using known techniques (e.g. tac welding). When the lid assembly is used to hermetically seal an electrical component contained within the package base, the solder is heated to attach the lid to the package base and contain the solder after heating entirely within the intended soldering area. Advantageously, due to the presence of the nickel in the center portion of the top surface of the lid, the solder resists flowing into the center and remains on the gold. This substantially reduces the number of defects during the assembly process. In one embodiment, four tac welds are used at the four corners of a square or rectangular preform.

In a subsequent step, not shown, the frame lid assembly is used to hermetically seal an electronic component that is mounted on a surface. The lid is positioned proximate to the electronic component such that the component is disposed under the exposed nickel while being surrounding by the solder preform. In one embodiment, the component resides within a cavity in the lid that was formed during stamping step 304. In a subsequent heating step, the solder adheres to the surface and thereby establishes a hermetic seal about the electronic component.

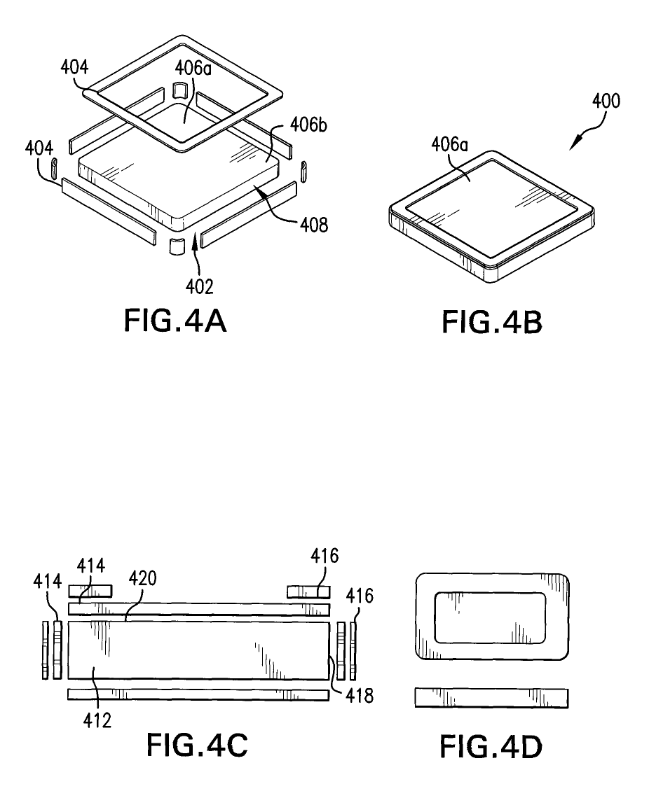

FIGS. 4A-4D are four views of two embodiments of the present invention. FIG. 4A is an exploded view of the plated frame 400 of FIG. 4B. The substrate 402 has gold plating 404 on its edge 408 and on a first portion 406b of the top surface of substrate 402. A second portion 406a of the top surface, which is circumscribed by portion 406b, is not gold-plated. Instead of being gold-plated, first portion 406a exposes its nickel-plated surface. FIGS. 4C and 4D are similar to FIGS. 4A and 4B except in that the substrate 412 is rectangular rather than square. Nickel plating 414 and gold plating 416 are shown. The gold plating is on edges 418 on the perimeter of top surface 420. In one embodiment, the nickel layer has a thickness between about 1 μm to about 6 μm and the gold layer has a thickness between about 0.1 μm to about 0.6 μm. It should be understood that gold layers 404 and 416 as well as nickel layer 414 are shown in an exploded view for illustration only.

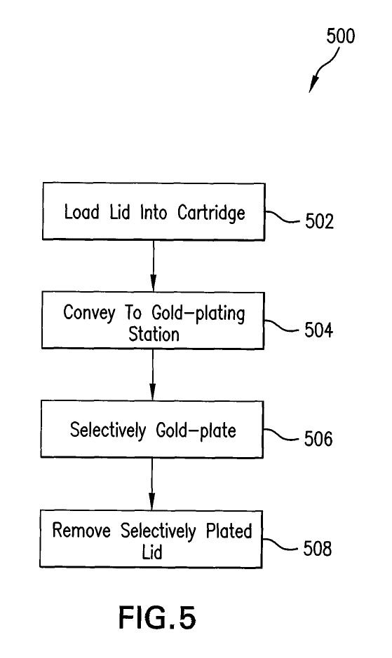

FIG. 5 is a flow diagram of one process 500 for selectively plating gold on a nickel-plated substrate. In step 502, each individual lid is loaded into a cartridge for subsequent plating. The cartridge, which may contain a number of lids, is then conveyed (step 504) to a gold-plating station where a current is applied to electroplate a layer of gold to the exposed surfaces (step 506). In step 508, the selectively plated lid is removed from the cartridge. In step 508, the mask is likewise removed to reveal the nickel surface that was formerly protected by the mask.

Process 600 is similar to process 500, but includes certain washing steps. Process 600 begins with step 602 wherein a nickel-plated frame is loaded into a cartridge. In step 604, the cartridge is conveyed to an acid washing station wherein the nickel surface is exposed to dilute acid. For example, the frame may be acid washed for about thirty seconds in a solution of 10-15% HCl at a temperature of 60° C. In step 606, the cartridge is then conveyed to a water washing station to remove trace acid. The water wash may be performed for about thirty seconds in a solution of de-ionized water at a temperature of 60° C. In step 608, which is similar to step 506 of process 500, the cartridge is conveyed to a gold-plating station for selective gold plating. In step 610, the selectively plating cartridge is conveyed to a water washing station which removes any residual gold solution. The cartridge is then conveyed to a drying station in step 612 where residual water is removed by heat and pressurized air. In one embodiment, the washed lid is removed from the cartridge prior to the drying step.

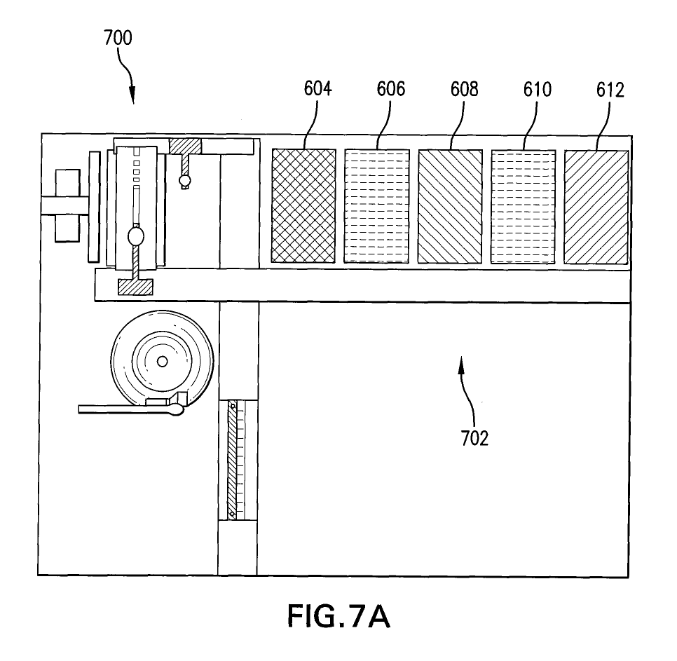

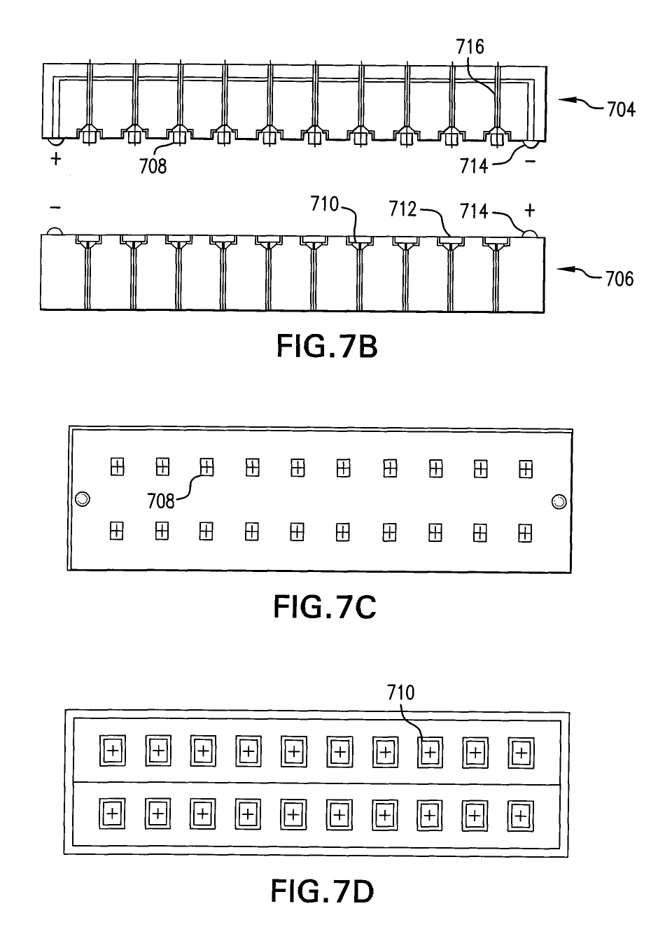

FIG. 7A is a schematic depiction of one machine which produces the inventive frame lid assemblies. The machine illustrated in FIG. 7A is configured to execute process 600. Multiple lids are loaded into cartridges on the left (zone 700) and thereafter sequentially conveyed to five stations (604, 606, 608, 610 and 612) in zone 702.

FIG. 7B is a schematic for one cartridge for use with the present invention. In the illustrated embodiment, lids 712 are provided to a pick and place station by a rotary bowl and thereafter loaded onto lower jig 706 as shown in FIG. 7B. The lower surface of lid 712 is protected by lower mask 710. A top jig 704 is then lowered to place it in contact with lower jig 706 to form the cartridge. In so doing, upper mask 708 protects a portion of the upper surface of lid 712. As can be seen by comparing the surface of top jig 704 (FIG. 7C) to the surface of bottom jig 706 (FIG. 7D), the lower mask 710 has a small area than that of upper mask 708. The surface of either jig may, in some embodiments, have a customized topography to selectively mask in a particular pattern. In the embodiments illustrated in FIGS. 7C and 7D, the topography of each mask is a rectangle. Top jig 704 includes an adjuster 716 operatively connected to upper mask 708. The adjuster may, for example, adjust the vertical position of the mask 708 by rotation of adjuster 716. Such an adjuster permits a single cartridge to accommodate several different thicknesses of lids. For example, by moving the upper mask 708 upward, a particular thick lid can be accommodated within the cartridge. Although the terms “upper jig” and “lower jig” have been used, it should be understood that these terms are for illustrative purposes only. The relative positions of the lower and upper masks may be reversed without negatively impacting the method and such a modification is considered within the scope of the invention. Similarly, the adjuster 716 can be part of the bottom jig.

The masks 708, 710 may be, for example, formed from a polymeric material, such as rubber. In one embodiment, the cartridge is an electroplating cartridge that includes anode and cathode connections 714 and corresponding electrical connections for conducting an electrical current through the lid to enable the electroplating process.

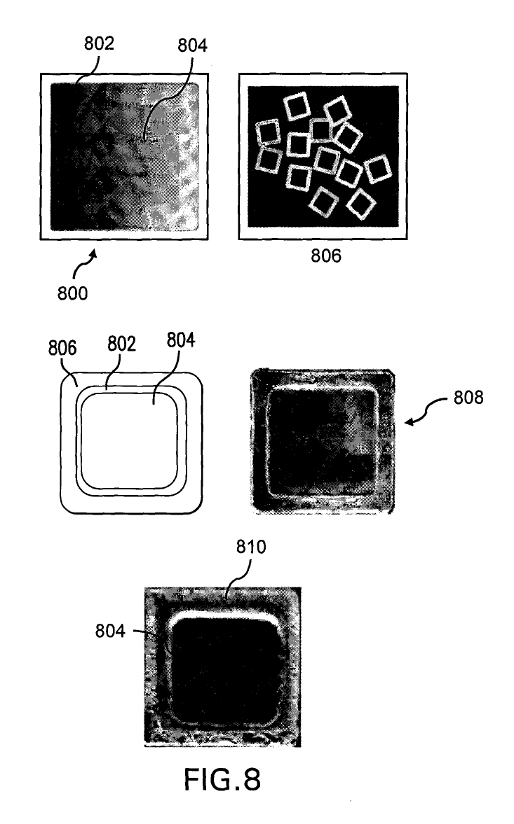

FIG. 8 shows lid 800 which includes selectively plated gold 802 and exposed nickel 804 on its upper surface. Preformed solder rings 806 are also shown. These two components are joined to form assembly 808. After thermal treatment, solder ring 806 is joined to the gold to provide frame lid assembly 810. In certain embodiments, the preform and gold plating are sized such that gold 802 extends beyond the edge of solder 806. In other words, the width of the gold 802 is wider than the width of solder 806.

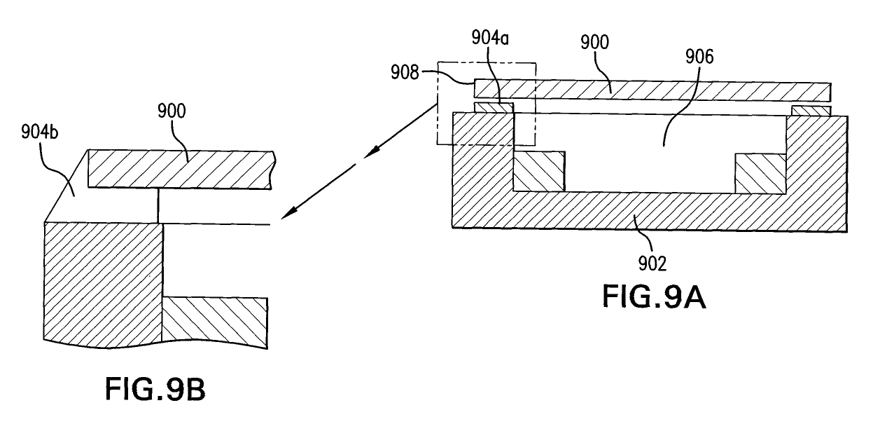

FIGS. 9A and 9B are depictions of a hermetically sealed package. Lid 900, which includes solder preform 904a hermetically seals space 906. Package 902 provides the lower base of this sealed system. When preform 904a is heated, it spreads along the horizontal gold surfaces (e.g. 802 in FIG. 8) as well as the gold-plated vertical edge 908 to form solder seal 904b. Such solder movement may be facilitated by applying downward pressure to the lid 900 during sealing which causes the solder to extrude outwardly.

The hermetic sealing and selective plating techniques described herein need not be limited to the production of lids. Other suitable applications include the selective plating of package bases for later use as die attach pads. The gold-plating provides a surface to which solder readily adheres.

While the invention has been described with reference to preferred embodiments, it will be understood by those skilled in the art that various changes may be made and equivalents may be substituted for elements thereof to adapt to particular situations without departing from the scope of the invention. Therefore, it is intended that the invention not be limited to the particular embodiments disclosed as the best mode contemplated for carrying out this invention, but that the invention will include all embodiments falling within the scope and spirit of the appended claims.

What is claimed is:

1. A method for manufacturing a frame lid assembly comprising the steps of:
providing a substrate with a top surface, a bottom surface opposite the top surface and an edge that circumscribes the substrate;
plating the top surface, the bottom surface and the edge with nickel;
applying a mask that covers the bottom surface and a first portion of the top surface while leaving the edge and a second portion of the top surface exposed; and
selectively plating the edge and second portion of the top surface with gold while the mask is applied, thereby preventing gold-plating of the bottom surface and the first portion of the top surface.

2. The method as recited in claim 1, further comprising the step of providing a preformed solder ring on the top surface after the step of selectively plating, such that the preformed solder ring is disposed on the gold that was plated on the second portion of the top surface and the ring circumscribes the first portion of the top surface.

3. The method as recited in claim 2, further comprising the step of heating the preformed solder ring to cause the solder to flow and thereby adhere to the gold.

4. The method as recited in claim 2, wherein the preformed solder ring has four corners and is in the shape of a square ring or rectangular ring, the method further comprising the step of spot welding at least one of the four corners.

5. The method as recited in claim 1, wherein the step of plating the top surface, the bottom surface and the edge with nickel deposits a layer of nickel with a thickness of from about 1 μm to about 6 μm.

6. The method as recited in claim 1, wherein the step of selectively plating the edge and second portion of the top surface with gold deposits a layer of gold with a thickness of from about 0.1 μm to about 0.6 μm.

7. A method for manufacturing a frame lid assembly comprising the steps of:
loading a nickel-plated substrate into an electroplating cartridge, wherein the substrate has a top surface, a bottom surface opposite the top surface and an edge that circumscribes the substrate, the cartridge having a mask that covers the bottom surface and a first portion of the top surface while leaving the edge and a second portion of the top surface exposed, the first portion circumscribing the second portion;
conveying the cartridge with the nickel-plated substrate to a gold-plating station;
selectively electroplating the edge and second portion of the top surface with gold while the mask is applied, thereby preventing gold-plating of the bottom surface and the first portion of the top surface to provide a selectively plated substrate; and
removing the selectively plated substrate from the cartridge.

8. The method as recited in claim 7, wherein, prior to the step of conveying the cartridge to a gold-plating station, conveying the cartridge to an acid-washing station and washing the nickel-plated substrate with acid.

9. The method as recited in claim 8, wherein, prior to the step of conveying the cartridge to a gold-plating station, conveying the cartridge to a water-washing station and washing the nickel-plated substrate with water.

10. The method as recited in claim 8, wherein, subsequent to the step of conveying the cartridge to a gold-plating station, conveying the cartridge to a water-washing station and washing the selectively plated substrate with water.

11. The method as recited in claim 8, wherein, subsequent to the step of conveying the cartridge to a gold-plating station, conveying the cartridge to a drying station and drying the selectively plated substrate.

12. The method as recited in claim 8, further comprising the step of disposing the frame lid assembly about an electronic component that is mounted on a surface and subsequently hermetically sealing the frame lid assembly about the electronic component.

13. The method as recited in claim 7, wherein the mask includes an upper mask and a lower mask and the electroplating cartridge comprises:
a lower jig with the lower masks that engage the bottom surface;
an upper jig with the upper masks that engage the second portion of the top surface; and
an anode and a cathode.

14. The method as recited in claim 13, wherein the lower mask and upper mask collectively define a lid-receiving zone with a thickness, the cartridge further comprises means for adjusting the thickness of the lid-receiving zone.

15. A frame lid assembly comprising:
an iron-containing substrate with a top, a bottom opposite the top and an edge that circumscribes the substrate;
a layer of nickel on the top, the bottom and the edge of the iron-containing substrate;
a layer of gold selectively deposited on the layer of nickel such that a first portion of the nickel on the top is exposed while the gold covers the edge and a second portion of nickel on the top, the second portion of nickel circumscribing the first portion.

16. The frame lid assembly as recited in claim 15, further comprising a preformed solder ring disposed on the gold and above the second portion of nickel such that the solder ring circumscribes the first portion of nickel while leaving the first portion exposed.

17. The frame lid assembly as recited in claim 15, wherein the layer of gold extends beyond the preformed solder ring.

18. An electroplating cartridge for selectively masking a lid comprising:
a lower jig with a plurality of lower masks on an exposed first surface;
an upper jig with a corresponding plurality of upper masks on an exposed second surface;
wherein each of the lower masks is positioned to engage a corresponding one of the upper masks to sandwich a lid therebetween at an upper and a lower contact area, the upper contact area and lower contact areas having different areas.
